(19) United States
(12) Patent Application Publication
(10) Pub. No.: US 2013/0047924 A1
(43) Pub. Date: Feb. 28, 2013

(54) SUBSTRATE PROCESSING APPARATUS AND FILM DEPOSITION APPARATUS

(71) Applicants: Tadashi Enomoto, Iwate (JP); Yukio Ohizumi, Iwate (JP); Manabu Honma, Iwate (JP)

(72) Inventors: Tadashi Enomoto, Iwate (JP); Yukio Ohizumi, Iwate (JP); Manabu Honma, Iwate (JP)

(73) Assignee: Tokyo Electron Limited, Tokyo (JP)

(21) Appl. No.: 13/590,524

(22) Filed: Aug. 21, 2012

(30) Foreign Application Priority Data
Aug. 30, 2011 (JP) 2011-187215

(51) Int. Cl. C23C 16/46

(52) U.S. Cl. 118/725

(57) ABSTRACT

A substrate processing apparatus includes a process chamber; a turntable rotatably provided in the process chamber for mounting a substrate on one surface of the turntable and including a substrate mounting portion at which the substrate is to be mounted and a table body which is an other portion of the turntable, the substrate mounting portion being configured to have a heat capacity smaller than that the table body; and a heater that heats the substrate from an opposite surface side of the turntable.

### CROSS-REFERENCE TO RELATED APPLICATION

The present application is based on Japanese Priority Application No. 2011-187215 filed on Aug. 30, 2011, the entire contents of which are hereby incorporated herein by reference.

### BACKGROUND OF THE INVENTION

1. Field of the Invention

The present invention relates to a substrate processing apparatus and a film deposition apparatus.

2. Description of the Related Art

In a method of manufacturing a semiconductor device, a process of forming a film on a surface of a substrate such as a semiconductor wafer (simply referred to as a “wafer” hereinafter) or the like is known. In this process, under a vacuum atmosphere, a first reaction gas is supplied to be adsorbed onto the wafer, then, a second reaction gas is supplied so that a single or plural atomic layers or molecular layers are formed on the wafer, and the cycle of supplying the first reaction gas and the second reaction gas is repeated plural times to form the film. This process is called Atomic Layer Deposition (ALD) or Molecular Layer Deposition (MLD), for example.

This process is used for forming a gate oxide film such as a silicon oxide film, a high dielectric constant film or the like. When forming a silicon oxide film (SiO₂ film), Bis Tertiary-Butylamino Silane (simply referred to as “BTBAS” hereinafter) gas is used as the first reaction gas (source gas), and ozone gas is used as the second reaction gas (oxidation gas), for example.

For performing the process, a film deposition apparatus is known that includes a turntable, on a surface of which a wafer is mounted, rotatably provided in a vacuum chamber and a heater provided at a back surface side of the turntable. Further, process areas to which reaction gasses are supplied are provided on the turntable and separating areas for preventing mixing of the reaction gasses are also provided on the turntable between the process areas in a rotational direction of the turntable. When forming the film, the wafer W is heated by the radiation heat of the heater via the turntable.

However, when the process of forming the film is repeated in the film deposition apparatus, depositions generated by the reaction gas are deposited on a surface of the turntable or on an inner wall of the vacuum chamber. In such a case, a cleaning process in which cleaning gas such as etching gas or the like is supplied in the vacuum chamber to remove the deposition is performed. Thus, the turntable needs to be made of a material having a high resistance against the cleaning gas supposed to be used in order to prevent corrosion by the cleaning gas.

However, there may be a case in which a heat capacity of the turntable becomes large when the turntable is made of the material having a high resistance against the cleaning gas. If the heat capacity of the turntable is large, the thermal conductivity from the heater to the wafer mounted on the turntable becomes low and it requires more time to heat the wafer to be a desired temperature. In such a case, throughput of the apparatus may be lowered.

Patent Document 1 discloses a technique in which thickness of the susceptor is varied along a radial direction of a substrate in order to equalize the temperature distribution of the substrate. Patent Document 2 discloses a susceptor to which a rib is provided for enforcement. However, the above problems still remain.

### PATENT DOCUMENT

### [Patent Document 1] Japanese Patent No. 2,514,788

### [Patent Document 2] Japanese Laid-open Patent Publication No. 2002-256439

### SUMMARY OF THE INVENTION

The present invention is made in light of the above problems, and provides a technique capable of efficiently heating a substrate mounted on a turntable.

According to an embodiment, there is provided a substrate processing apparatus including a process chamber; a turntable rotatably provided in the process chamber for mounting a substrate on one surface of the turntable and including a substrate mounting portion at which the substrate is to be mounted and a table body which is an other portion of the turntable, the substrate mounting portion being configured to have a heat capacity smaller than that of the table body; and a heater that heats the substrate from an opposite surface side of the turntable.

According to another embodiment, there is provided a film deposition apparatus for forming a film on a substrate including, a process chamber; a turntable rotatably provided in the process chamber for mounting a substrate on one surface of the turntable and including a substrate mounting portion at which the substrate is to be mounted and a table body which is an other portion of the turntable, the substrate mounting portion being configured to have a heat capacity smaller than that of the table body; and a heater that heats the substrate from an opposite surface side of the turntable.

### BRIEF DESCRIPTION OF THE DRAWINGS

Other objects, features and advantages of the present invention will become more apparent from the following detailed description when read in conjunction with the accompanying drawings.

FIG. 1 is a cross-sectional view of a film deposition apparatus of an embodiment;

FIG. 2 is a perspective view of the film deposition apparatus of an embodiment;

FIG. 3 is a plan view of the film deposition apparatus of an embodiment;

FIG. 4 is a partial cross-sectional view of a turntable of an embodiment;

FIG. 5 is an exploded view of the turntable seen from a front surface side of an embodiment;

FIG. 6 is a partial perspective view of the turntable seen from a back surface side of an embodiment;

FIG. 7 is a plan view showing flows of gasses generated in the film deposition apparatus of an embodiment;

FIG. 8 is a partial cross-sectional view showing another example of a turntable; and

FIG. 9 is a perspective view of another example of a turntable.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated.

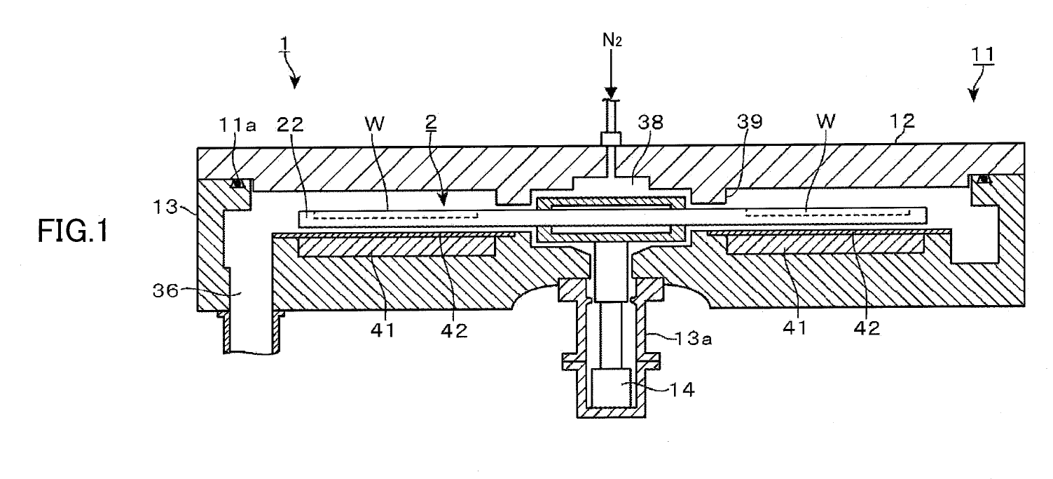

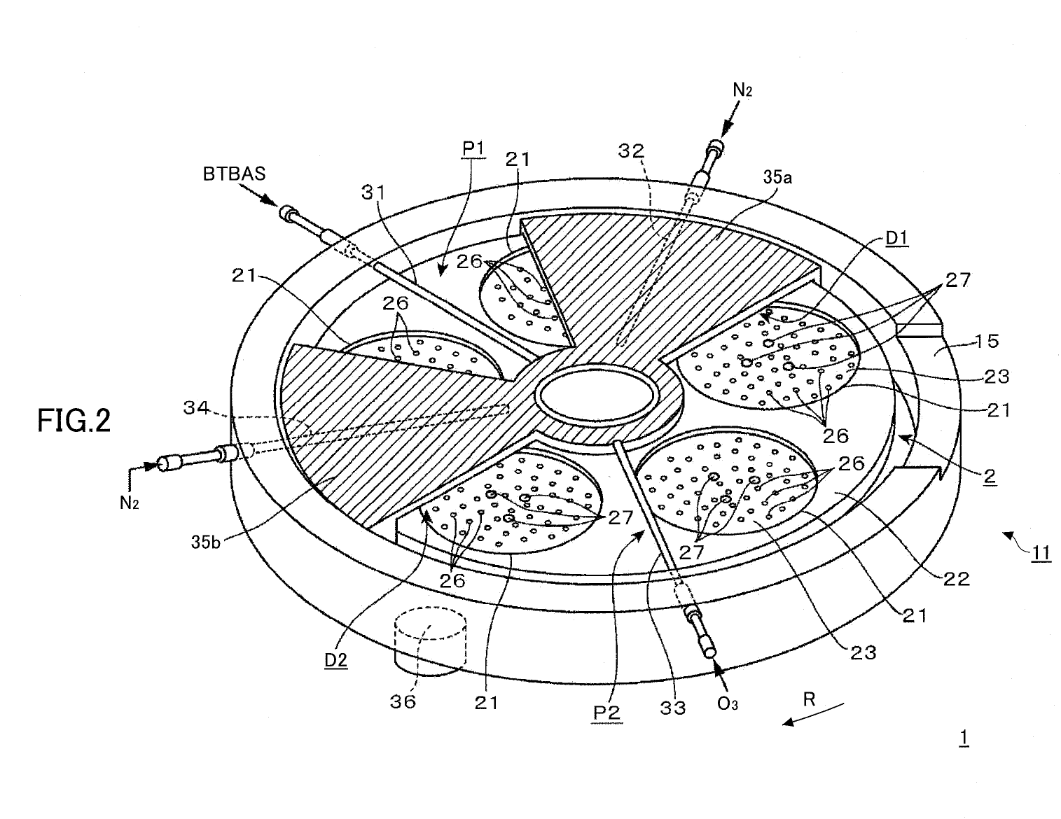

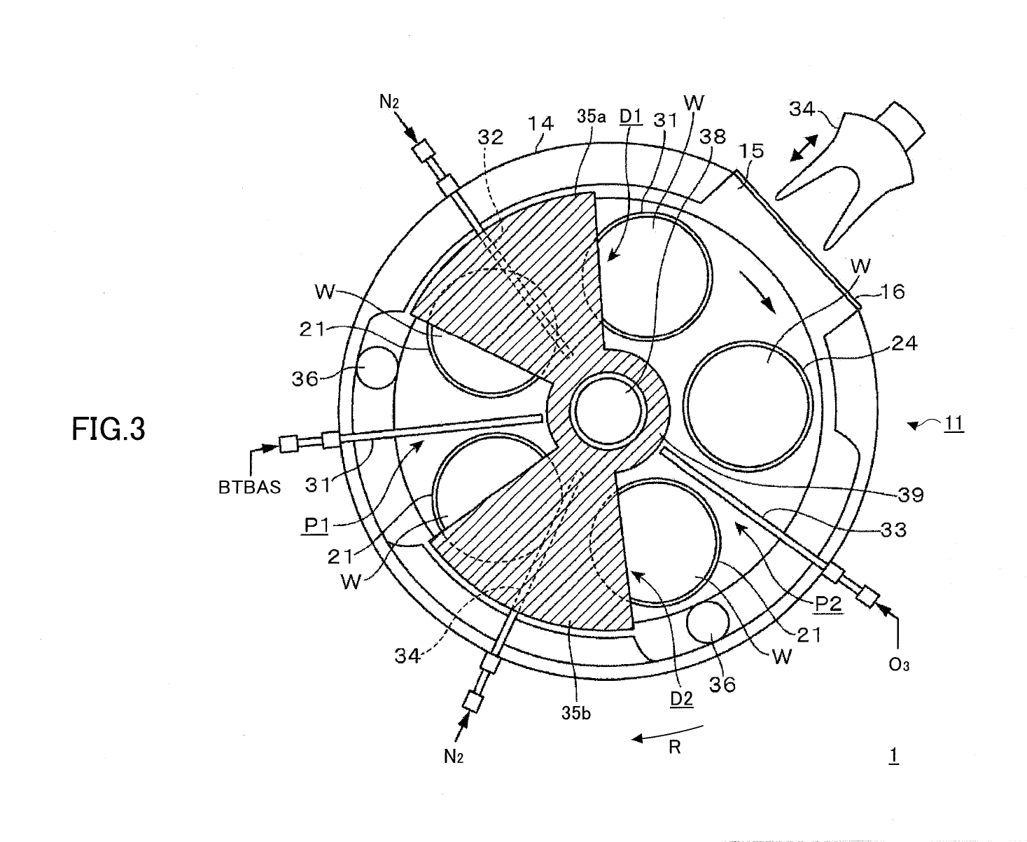

FIG. 1 is a cross-sectional view of a film deposition apparatus 1, FIG. 2 is a perspective view of the film deposition apparatus 1, and FIG. 3 is a plan view of the film deposition apparatus 1.

The film deposition apparatus 1 performs Atomic Layer Deposition (ALD) and/or Molecular Layer Deposition (MLD) on a wafer W, which is an example of a substrate. The film deposition apparatus 1 includes a substantially flat circular shaped vacuum chamber (an example of a process chamber) 11, a turntable 2, a rotary drive mechanism 14, a heater 41, a shield member 42, and evacuation ports 36.

The vacuum chamber 11 is provided in atmosphere. The vacuum chamber 11 includes a ceiling plate 12, a chamber body 13 that composes a sidewall and a bottom portion of the vacuum chamber 11, a seal member 11a for maintaining inside of the vacuum chamber 11 airtight, and a cover 13a for covering a center portion of the chamber body 13.

The turntable 2 has a circular shape and is horizontally provided in the vacuum chamber 11. The turntable 2 is connected to the rotary drive mechanism 14 and is rotated around a center axle of the rotary drive mechanism 14 by the rotary drive mechanism 14.

As shown in FIG. 2 and FIG. 3, the turntable 2 is provided with plural (five in this embodiment) concave portions 21 at a front surface along a rotational direction R. The wafers W are mounted on the concave portions 21, respectively (see FIG. 3). The wafers W are rotated in accordance with the rotation of the turntable 2 around the center axle of the rotary drive mechanism 14.

The turntable 2 includes a table body 22 and plural wafer mounting plates 23 (an example of a substrate mounting portion) provided at positions corresponding to the concave portions 21, respectively. The structure of the turntable 2 will be explained later in detail.

The vacuum chamber 11 is further provided with a transfer opening 15 for transferring the wafers W into and from the vacuum chamber 11 and a shutter 16 capable of opening and closing the transfer opening 15 (see FIG. 3, not shown in FIG. 2).

The film deposition apparatus 1 further includes a first reaction gas nozzle 31, a separation gas nozzle 32, a second reaction gas nozzle 33, and a separation gas nozzle 34 provided above the turntable 2. The first reaction gas nozzle 31, the separation gas nozzle 32, the second reaction gas nozzle 33, and the separation gas nozzle 34 are respectively formed in a stick shape extending from an outer periphery toward a center of the turntable 2. The first reaction gas nozzle 31, the separation gas nozzle 32, the second reaction gas nozzle 33, and the separation gas nozzle 34 are provided in the rotational direction R in this order. These gas nozzles 31 to 34 are respectively provided with plural openings at a respective lower side to supply the respective gasses along the radius of the turntable 2. The first reaction gas nozzle 31 and the second reaction gas nozzle 33 are examples of reaction gas supplying units.

As an example, when forming a film, the first reaction gas nozzle 31 supplies BTBAS (Bis Tertiary-Butylamino Silane) gas, the second reaction gas nozzle 33 supplies O₃ (ozone) gas, and the separation gas nozzles 32 and 34 supply N₂ (nitrogen) gas, respectively.

Further, in this embodiment, the film deposition apparatus 1 performs a cleaning process in which depositions generated from the reaction gasses when forming the film onto the wafers W and deposited on a surface of the turntable 2 or on an inner wall of the vacuum chamber 11 are removed. As an example, in the cleaning process, cleaning gas is supplied from the first reaction gas nozzle 31 and the second reaction gas nozzle 33 instead of BTBAS gas and O₃ gas, respectively. The cleaning gas may be a gas containing halogen such as chlorine, fluorine or the like.

The ceiling plate 12 of the vacuum chamber 11 is provided with substantially fan-shaped two protruding portions 35a and 35b protruding downward. The protruding portions 35a and 35b are spaced apart from each other in a circumferential direction (in the rotational direction R). The separation gas nozzles 32 and 34 are provided to be embedded in the protruding portions 35a and 35b and divide the protruding portions 35a and 35b in the circumferential direction, respectively. The first reaction gas nozzle 31 and the second reaction gas nozzle 33 are provided to be apart from the protruding portions 35a and 35b.

It is assumed that a gas supplying area below the first reaction gas nozzle 31 is referred to as a “first process area P1” and a gas supplying area below the second reaction gas nozzle 33 is referred to as a “second process area P2”. Further, it is assumed that areas below the protruding portions 35a and 35b are referred to as separating areas D1 and D2, respectively.

In this embodiment, the vacuum chamber 11 is provided with two evacuation ports 36 at a bottom surface. The evacuation ports 36 are provided at outside of the outer periphery of the turntable 2 in the radial direction near the first process area P1 between the first reaction gas nozzle 31 and the separating area D1 in the rotational direction R of the turntable 2, and near the second process area P2 between the second reaction gas nozzle 33 and the separating area D2 in the rotational direction R of the turntable 2.

When forming the film, N₂ gas supplied from the separation gas nozzles 32 and 34 to the separating areas D1 and D2 spreads in the separating areas D1 and D2 in the circumferential direction to prevent mixing of BTBAS gas and O₃ gas on the turntable 2 and flows with the BTBAS gas and O₃ gas to the evacuation ports 36, respectively.

Further, when forming the film, N₂ gas is supplied to a center portion area 38 of the turntable 2. N₂ gas supplied to the center portion area 38 is further supplied toward outside of the turntable 2 in the radial direction via a lower portion of a ring shaped protruding portion 39 which is provided at the ceiling plate 12 to protrude downward. With this, mixing of BTBAS gas and O₃ gas at the center portion area 38 can also be prevented. Further, although not shown in the drawings, N₂ gas is also supplied in the cover 13a and a back surface side of the turntable 2 so that the reaction gasses are purged.

The heater 41 is provided at a bottom portion of the vacuum chamber 11, in other words, at a lower side of the turntable 2, to be apart from the turntable 2. The temperature of the turntable 2 is raised by the radiation heat transferred from the heater 41 to the turntable 2 so that the wafers W mounted on the concave portions 21 are also heated. The heater 41 is provided with the shield member 42 at the surface for preventing a film to be formed on a surface of the heater 41.

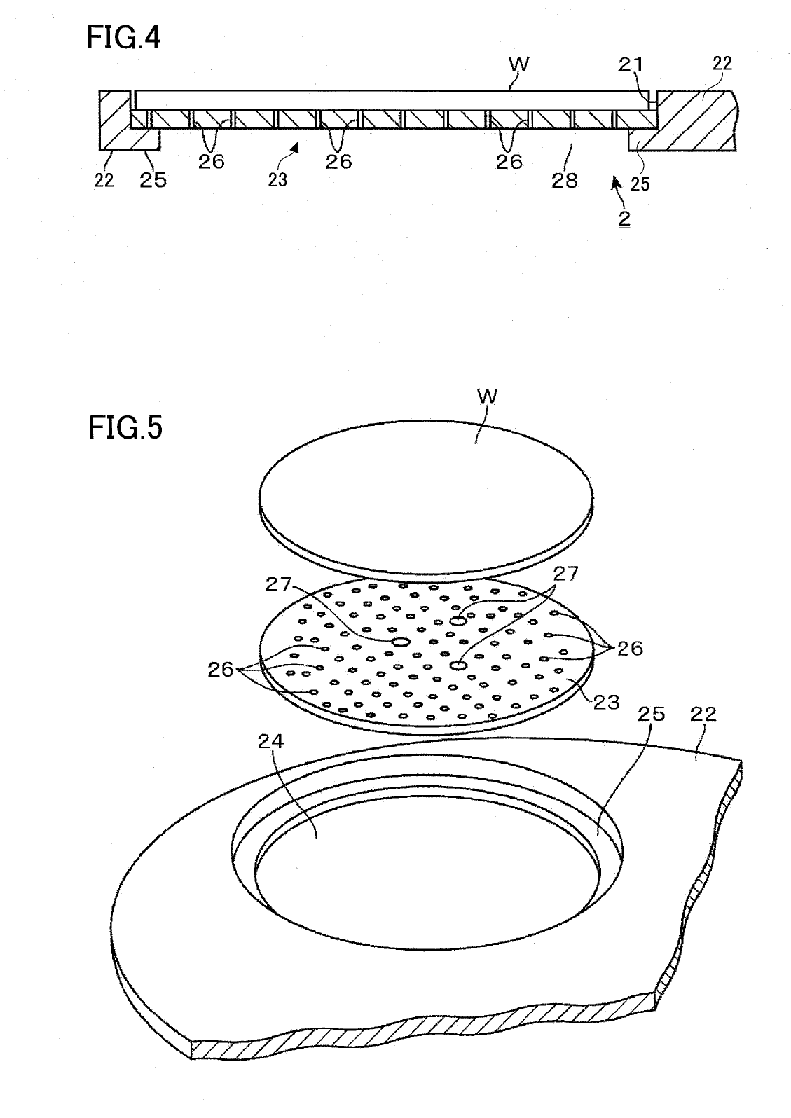

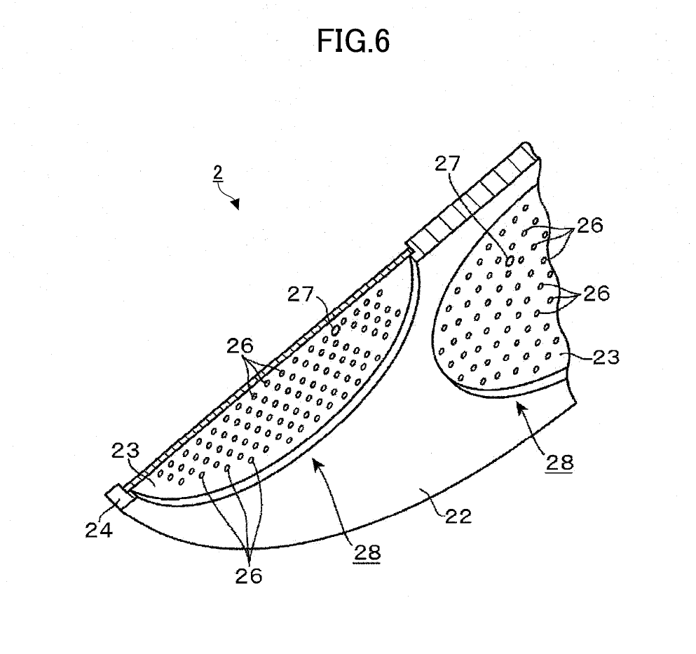

The structure of the turntable 2 is explained in detail with reference to FIG. 4 to FIG. 6 as well. FIG. 4 is a partial cross-sectional view of the turntable 2, FIG. 5 is an exploded view of the turntable 2 seen from the front surface side, and FIG. 6 is a partial perspective view of the turntable 2 seen from the back surface side.

As explained above, the turntable 2 includes the table body 22 that forms an outer shape of the turntable 2, and the plural wafer mounting plates 23. The wafer mounting plates 23 form the mounting areas of the wafers W, respectively. In this embodiment, the outer areas of the mounting areas of the wafers W are formed of the table body 22 in the turntable 2.

The table body 22 is provided with plural (five in this embodiment) penetrated opening portions 24 each having a circular shape at positions corresponding to the plural concave portions 21 shown in FIG. 2 and FIG. 3. The table body 22 is provided with ring shaped support portions 25 at a lower side of a side wall of each of the penetrated opening portions 24. Each of the support portions 25 protrudes toward inside of the respective penetrated opening portion 24. The support portion 25 is configured to support an outer periphery of the respective wafer mounting plate 23. Thus, the diameter of the inner edge of the support portion 25 is made smaller than the diameter of the outer edge of the respective wafer mounting plate 23. When the wafer mounting plates 23 are supported by the support portions 25 formed within the penetrated opening portions 24, the concave portions 21 are formed at the front surface of the turntable 2, respectively.

Further, in this embodiment, the table body 22 is configured to have a high resistance against the gasses used in the film deposition apparatus 1. Specifically, the table body 22 may be composed of a material having a high resistance against the gasses used in the film deposition apparatus 1. Especially, the table body 22 may be composed of a material having a high corrosion resistance against the cleaning gas used in the cleaning process. The table body 22 is made of quartz, in this embodiment.

In this embodiment, the wafer mounting plates 23 and the table body 22 are made of different materials. Specifically, in this embodiment, the turntable 2 is configured such that the wafer mounting plates 23 have a heat capacity smaller than that of the table body 22.

In this embodiment, each of the wafer mounting plates 23 includes a material, as a major constituent, having a specific heat capacity smaller than that of the material mainly composing the table body 22. As an example, each of the wafer mounting plates 23 may be composed of a single material having a specific heat capacity smaller than that of the material mainly composing the table body 22. Alternatively, each of the wafer mounting plates 23 may be mainly composed of a material having a specific heat capacity smaller than that of the material mainly composing the table body 22 which is coated with another material.

Further in this embodiment, each of the wafer mounting plates 23 may includes a material, as a major constituent, having a coefficient of thermal conductivity higher than that of the material mainly composing the table body 22. As an example, each of the wafer mounting plates 23 may be composed of a single material having a coefficient of thermal conductivity higher than that of the material mainly composing the table body 22. Alternatively, each of the wafer mounting plates 23 may be mainly composed of a material having a coefficient of thermal conductivity higher than that of the material mainly composing the table body 22 which is coated with another material.

Here, “as a major constituent” means that the content (volume ratio) of the material is the highest among other constituents or the content (volume ratio) of the material is more than 50%.

Each of the wafer mounting plates 23 may be composed of ceramics such as aluminum nitride (AlN), silicon carbide (SiC) or the like, a carbon containing material such as carbon (graphite) or the like. Each of the wafer mounting plates 23 is made of aluminum nitride (AlN), in this embodiment.

With this structure, the wafer mounting plates 23 can rapidly raise the temperature of the wafers W mounted on the wafer mounting plates 23, respectively, when heated by the radiation heat of the heater 41.

Further, the wafer mounting plates 23 are configured to be positioned from the front surface to the back surface of the turntable 2. With this structure, the wafer mounting plates 23 can rapidly and efficiently raise the temperature of the wafers W mounted on the wafer mounting plates 23, respectively, when heated by the radiation heat of the heater 41.

Each of the wafer mounting plates 23 is formed to have a circular shape corresponding to the shape of the respective penetrated opening portion 24 and is detachably attached to the table body 22.

Further, each of the wafer mounting plates 23 is provided with plural through-holes for reducing heat capacity 26 which penetrate the respective wafer mounting plate 23 from the front surface to the back surface. The plural through-holes for reducing heat capacity 26 are dispersed in the respective wafer mounting plate 23. In this embodiment, the plural through-holes for reducing heat capacity 26 are substantially equally dispersed at the entirety of the surface of the respective wafer mounting plate 23. By providing such the plural through-holes for reducing heat capacity 26, heat capacity of the wafer mounting plate 23 can further be reduced.

The wafer mounting plate 23 is further provided with three through-holes for elevation pins 27. The diameter of the through-holes for elevation pins 27 may be made larger than that of the through-holes for reducing heat capacity 26. The through-holes for elevation pins 27 are provided to pass the elevation pins (not shown in the drawings) which are provided below the turntable 2. The wafer W is transferred between the wafer transfer mechanism 3A shown in FIG. 3 and the turntable 2 by the elevation pins. In other words, in this embodiment, the wafer mounting plate 23 is provided with the plural through-holes for reducing heat capacity 26 for transferring the heat from the heater 41 to the respective wafer W in addition to the three through-holes for elevation pins 27.

The turntable 2 is further provided with back surface side concave portions 28 at the back surface of the turntable 2 which are formed by the wafer mounting plate 23 and the inner wall of the support portions 25, respectively. By structuring the table body 22 and the wafer mounting plates 23 such that the back surface side concave portions 28 are also formed at the back surface of the turntable 2, the wafer mounting plates 23 can be made further thinner than that of the table body 22 so that the turntable 2 is strengthened by the table body 22. Thus, the heat capacity of the wafer mounting plates 23 can be made smaller to rapidly raise the temperature of the wafers W. Here, the wafer mounting plates 23 may be formed to have a thickness sufficient enough to hold the wafers W, respectively.

Here, in order to reduce the heat capacity of the wafer mounting plate 23, the plane area of the support portion 25 may be as small as possible as long as the respective wafer mounting plate 23 and wafer W are sufficiently supported. In this embodiment, the plane area of the support portion 25 may be less than 30% of that of the respective wafer mounting plate 23, for example. It means that the penetrated opening portions 24 or the back surface side concave portions 28 are formed to correspond to the major part of the respective wafer mounting plate 23 (or that of the wafer W to be mounted on the wafer mounting plate 23). Specifically, the plane area of the penetrated opening portions 24, in other words, the plane area of the back surface side concave portions 28 is more than or equal to 70% that of the respective wafer mounting plate 23 (or that of the wafer W to be mounted on the wafer mounting plate 23).

The operation of the film deposition apparatus 1 is explained.

When the wafer transfer mechanism 3A passes into the vacuum chamber 11 from the transfer opening 15 while holding the wafer W, the elevation pins (not shown in the drawings) protrude from the through-holes for elevation pins 27 provided in the wafer mounting plate 23 at a position facing the transfer opening 15 above the turntable 2 to receive the wafer W. Thus, the wafer W is transferred from the wafer transfer mechanism 3A to the wafer mounting plate 23. When the wafers W are mounted in all of the concave portions 21, the vacuum chamber 11 is evacuated by vacuum pumps (not shown in the drawings) connected to the two evacuation ports 36, respectively. Thus, inside of the vacuum chamber 11 becomes a vacuum atmosphere at a predetermined pressure. Then, the turntable 2 is rotated and the heater 41 starts heating.

With this operation, the radiation heat transferred by the heater 41 toward the turntable 2 increases and the wafer mounting plates 23 of the turntable 2 rapidly become a target temperature, 350° C. for example, quicker than the table body 22. Thus, by the heat transferred from the wafer mounting plates 23, the wafers W are heated to the target temperature, 350° C. for example, and an output from the heater 41 is maintained at a predetermined value.

Subsequently, gasses are supplied from the gas nozzles 31 to 34, respectively. The wafers W alternately pass through the first process area P1 below the first reaction gas nozzle 31 and the second process area P2 below the second reaction gas nozzle 33. With this operation, BTBAS gas is adsorbed onto the wafers W and then O₃ gas is adsorbed onto the wafers W to oxidize BTBAS molecules to form a single or plural molecular layers of silicon oxide. By repeating the cycle, the molecular layers of silicon oxide are stacked and a silicon oxide film with a desired thickness is formed on each of the wafers W.

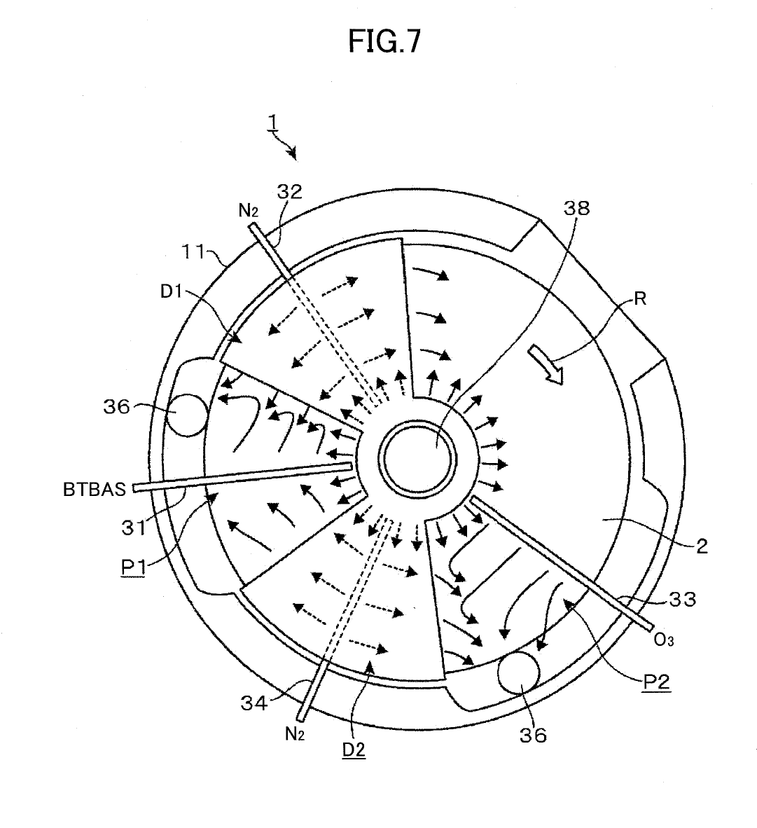

FIG. 7 is a plan view showing flows of gasses generated in the vacuum chamber 11. The arrow R shows the rotational direction of the turntable 2.

N₂ gas supplied from the separation gas nozzles 32 and 34 to the separating areas D1 and D2 spread in the separating areas D1 and D2 in the circumferential direction of the turntable 2 to prevent mixing of BTBAS gas and O₃ gas on the turntable 2. Further, N₂ gas is supplied to a space above the center portion area 38 of the turntable 2 when forming the film. N₂ gas is supplied toward the outside of the turntable 2 in the radial direction of the turntable 2 via below the ring shaped protruding portion 39 which protrudes downward at the ceiling plate 12 so that mixing of BTBAS gas and O₃ gas in the center portion area 38 is prevented. Further, although not shown in the drawings, N₂ gas is also supplied in the cover 13a and the back surface side of the turntable 2 so that the reaction gasses are purged.

After the turntable 2 is rotated for a predetermined time and a silicon oxide film with a desired thickness is formed, supplying of the gasses is terminated, the heater 41 is switched off and the temperature of the wafers W becomes lower from 350° C. Then, the elevation pins are moved upward so that the wafer W in the respective concave portion 21 is raised. Subsequently, the wafer transfer mechanism 3A receives the raised wafer W to be transferred outside the vacuum chamber 11.

Next, a cleaning process is explained.

After the process of forming the film is performed for a predetermined time, for example, the cleaning process is performed. In the cleaning process, the cleaning gas is supplied from the first reaction gas nozzle 31 and the second reaction gas nozzle 33 instead of BTBAS gas and O₃ gas, respectively. The cleaning process is performed similarly to the process of forming the film except that the kinds of gasses are different and the wafers W are not mounted on the turntable 2. As described above, the depositions deposited on the surface of the turntable 2 or on the inner wall of the vacuum chamber 11 are etched to be removed by the cleaning gas. As described above, the table body 22 of the turntable 2 of the embodiment has a high resistance against the gasses used in the film deposition apparatus 1. Thus, the deterioration of the turntable 2 by the cleaning process can be suppressed. Further, even if the wafer mounting plates 23 are damaged, the wafer mounting plates 23 can be changed to new ones after the cleaning process is performed a predetermined time.

According to the film deposition apparatus 1 of the embodiment, as the turntable 2 is configured such that the wafer mounting plates 23 have a heat capacity smaller than that of the table body 22, the temperature of the wafers W can be rapidly raised when heating the wafers W.

Specifically, for example, by forming the table body 22 of quartz while composing the wafer mounting plates 23 of ceramics such as aluminum nitride (AlN), silicon carbide (SiC) or the like, a carbon-containing material such as carbon (graphite) or the like, which has a smaller specific heat capacity than that of quartz, high corrosion resistance can be obtained while the temperature of the wafers W can be rapidly raised when heating the wafers W.

Thus, lowering of throughput can be suppressed. Further, as the wafer mounting plates 23 are detachably attached to the table body 22, the wafer mounting plate 23 can be independently changed to a new one when the wafer mounting plate 23 is damaged in the cleaning process. Thus, the maintenance of the film deposition apparatus 1 becomes easier.

Further, by configuring the turntable 2 such that the wafer mounting plates 23 have a heat capacity smaller than that of the table body 22, the wafers W can be rapidly cooled when terminating heating of the wafers W. With this structure, lowering of throughput can also be suppressed.

Alternative examples are explained.

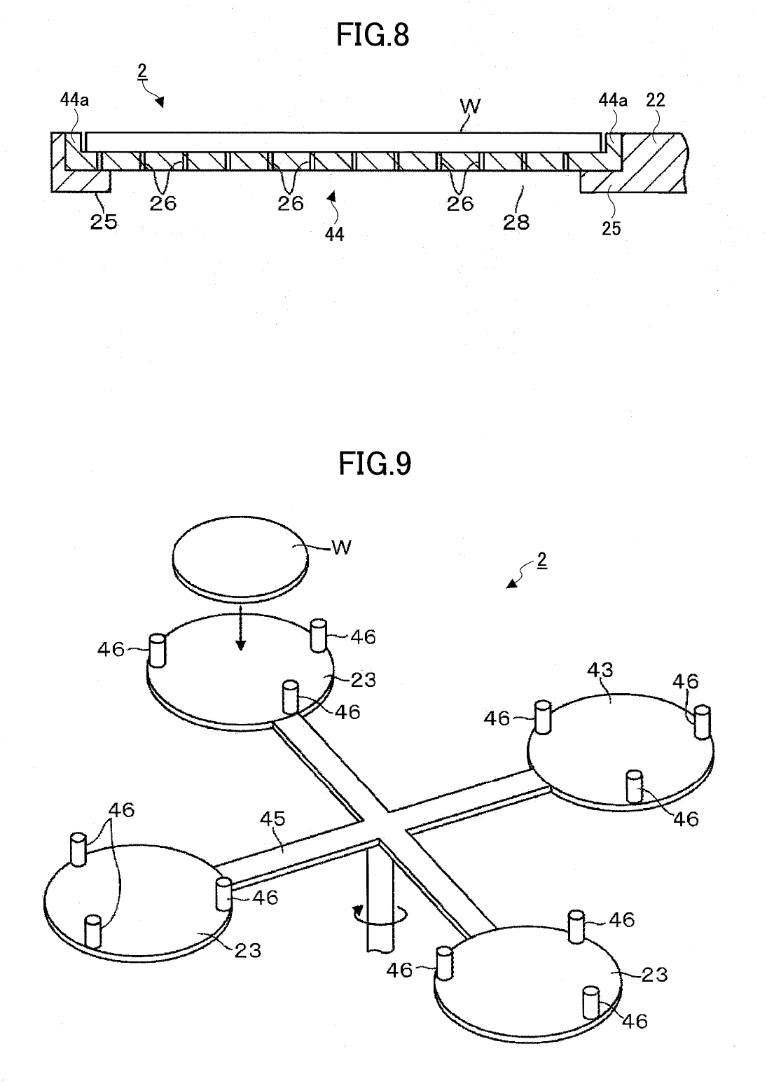

FIG. 8 is a partial cross-sectional view showing another example of the turntable 2 where wafer mounting plates are different from those shown in FIG. 4.

In this example, each of the wafer mounting plates 44 is provided with a protruding portion 44a formed at a periphery to protrude upward. In such a case, the wafer mounting plate 44 composes not only the bottom portion of the concave portion 21 but also the side wall of the concave portion 21. The wafer mounting plate 44 may be composed of the same material as the wafer mounting plate 23 which is explained above with reference to FIG. 4 to FIG. 6.

FIG. 9 is a perspective view of another example of a turntable.

In this example, a table body 45 of the turntable 2 is composed of a cross shaped plate having a cross shape not a circular shape. The wafer mounting plates 23 are provided at edges of the cross shaped plate of the table body 45. Further, plural pins 46 are provided at a surface of each of the wafer mounting plates 23 for aligning the wafer W on the respective wafer mounting plate 23 and holding the wafer W on the respective wafer mounting plate 23 when the table body 45 is rotated. The table body 45 may be composed of the same material as the table body 22 which is explained above with reference to FIG. 4 to FIG. 6.

In the above description, “the wafer mounting plate 23 is detachably attached to the table body 22” includes a case where the wafer mounting plate 23 is placed on the table body 22, a case where the table body 22 and the wafer mounting plate 23a are fitted with each other such as a protruding portion is provided on one of the table body 22 and the wafer mounting plate 23, and a concave portion corresponding to the protruding portion is provided on the other of the table body 22 and the wafer mounting plate 23 so that the protruding portion and the concave portion are fitted with each other, a case where the table body 22 and the wafer mounting plate 23 are fixed by a fixing member such as a screw, or the like.

Further, alternatively, reaction gas may be supplied onto the wafers W in one of the process areas P1 and P2 so that a film is formed and inactive gas may be supplied on the wafers W in the other of the process areas P1 and P2 to anneal the film.

Further, alternatively, a reaction gas may be supplied onto the wafers W in one of the process areas P1 and P2 so that a film is formed and oxidation gas is supplied while plasma is being applied onto the wafers W in the other of the process areas P1 and P2 so that the film is oxidized.

Further, the above embodiment may be applied to a substrate processing apparatus in which an etching process or the like is performed in one of or both of the process areas P1 and P2 by providing a certain gas onto the films formed on the wafers W, respectively.

Further, gasses of the same kind but with different concentrations may be supplied in the first process area P1 and the second process area P2 to form films or etch films on the wafers W, respectively. Further, three or more process areas may be provided on the turntable 2.

Alternative examples will be further explained.

The table body 22 and the wafer mounting plate 23 may be made of the same material.

For example, the table body 22 may also be made of ceramics such as aluminum nitride (AlN), silicon carbide (SiC) or the like, a carbon containing material such as carbon (graphite) or the like. In such a case, the wafer mounting plate 23 may be made of the same material as that of the table body 22, or may be made of a material having a specific heat capacity smaller than that of the material composing the table body 22.

Even when the same material is used for the table body 22 and the wafer mounting plate 23, by having the thickness of the portions of the wafer mounting plate 23 less than that of the table body 22 by forming concave portions at the back surface of the table body 22 as described above and/or by forming the through-holes for reducing heat capacity in the wafer mounting plate 23, the wafer mounting plates 23 can be configured to have a heat capacity smaller than that of the table body 22.

Further, the wafer mounting plates 23 and the table body 22 of the turntable 2 may be integrally formed of the same material. Even in such a case, by having the thickness of the wafer mounting plate 23 less than that of the table body 22 by forming concave portions at the back surface of the table body 22 as described above and/or by forming the through-holes for reducing heat capacity in the wafer mounting plate 23, the wafer mounting plates 23 can be configured to have a heat capacity smaller than that of the table body 22.

Further, when the wafer mounting plates 23 or the table body 22 are mainly composed of graphite, the graphite may be coated with silicon carbide (SiC) or the like.

According to the embodiment, the substrate mounted on the turntable can be efficiently heated to suppress lowering of throughput of the apparatus.

Further, the following embodiments are also included.

There is provided a substrate processing apparatus in which a substrate, which is mounted on a mounting area at one surface of a turntable provided in a process chamber, is processed with gasses by rotating the substrate in accordance with a rotation of the turntable. The substrate processing apparatus includes plural reaction gas supplying units for respectively supplying reaction gasses to plural process areas, separating areas provided between the process areas in a rotational direction for separating atmospheres of the plural process areas, an evacuation port for evacuating the process chamber, and a heater for heating the substrate with the radiation heat transferred from an opposite surface side of the mounting area. The turntable includes a substrate mounting portion corresponding to the mounting area that is formed on the one surface opposed to the opposite surface side of the turntable, and a table body which is a portion of the turntable other than the substrate mounting portion. The substrate mounting portion is configured to have a heat capacity smaller than that of the table body.

The substrate mounting portion may be detachably attached to the table body in the turntable.

The turntable may be provided with concave portions at a back surface and the bottom portions of the concave portions are farmed by the substrate mounting portions.

Plural through-holes may be provided in the substrate mounting portion from a front surface to the back surface of the turntable.

The plural through-holes may include through-holes for elevation pins through which elevation pins for mounting a substrate on the substrate mounting portion pass, and through-holes for suppressing the heat capacity of the substrate mounting portion. The elevation pins do not pass through the through-holes for suppressing the heat capacity.

The turntable may be provided with concave portions in which the substrates are mounted, respectively at the front surface and the bottom portions of the concave portions are formed by the substrate mounting portions.

The table body may be made of quartz and the substrate mounting portion is made of aluminum nitride, silicon carbide, carbon (graphite) or the like.

Further, there is provided a film deposition apparatus in which a thin film is formed on a substrate, which is mounted on a mounting area at one surface of a turntable provided in a process chamber, by supplying plural kinds of reaction gasses in order onto the substrate to stack layers of a reaction product while rotating the substrate in accordance with a rotation of the turntable. The film deposition apparatus includes plural reaction gas supplying units for respectively supplying reaction gasses to plural process areas, separating areas provided between the process areas in the rotational direction for separating atmospheres of the plural process areas, an evacuation port for evacuating the process chamber, and a heater for heating the substrate by the heat radiation from the opposite surface side of the mounting area. The turntable includes a substrate mounting portion corresponding to the mounting area that is formed on the one surface opposed to the opposite surface side of the turntable, and a table body which is a portion of the turntable other than the substrate mounting portion. The substrate mounting portion is configured to have a heat capacity smaller than that of the table body.

Although a preferred embodiment of the substrate processing apparatus and the film deposition apparatus has been specifically illustrated and described, it is to be understood that minor modifications may be made therein without departing from the sprit and scope of the invention as defined by the claims.

The present invention is not limited to the specifically disclosed embodiments, and variations and modifications may be made without departing from the scope of the present invention.

What is claimed is:

1. A substrate processing apparatus comprising:
a process chamber;
a turntable rotatably provided in the process chamber for mounting a substrate on one surface of the turntable and including a substrate mounting portion at which the substrate is to be mounted and a table body which is an other portion of the turntable, the substrate mounting portion being configured to have a heat capacity smaller than that of the table body; and
a heater that heats the substrate from an opposite surface side of the turntable.

2. The substrate processing apparatus according to claim 1,
wherein the substrate mounting portion includes a material, as a major constituent, having a specific heat capacity smaller than that of a material mainly composing the table body of the turntable.

3. The substrate processing apparatus according to claim 1,
wherein the table body is provided with a penetrated opening portion formed at a position corresponding to the substrate mounting portion, and the substrate mounting portion is formed to cover the penetrated opening portion of the table body.

4. The substrate processing apparatus according to claim 3,
wherein the substrate mounting portion is detachably attached to the table body.

5. The substrate processing apparatus according to claim 1,
wherein the turntable is provided with a concave portion at the opposite surface of the turntable at a position corresponding to the substrate mounting portion.

6. The substrate processing apparatus according to claim 1,
wherein the substrate mounting portion is provided with plural through-holes for reducing heat capacity which penetrate from the one surface to the opposite surface of the turntable.

7. The substrate processing apparatus according to claim 6,
wherein the substrate mounting portion is further provided with plural through-holes for elevation pins which penetrate from the one surface to the opposite surface of the turntable in addition to the plural through-holes for reducing heat capacity, which elevation pins move the substrate to be mounted on the substrate mounting portion upward and downward with respect to the substrate mounting portion, passing through the plural through-holes for elevation pins.

8. The substrate processing apparatus according to claim 1,
wherein the turntable is provided with a concave portion at the one surface at a position corresponding to the substrate mounting portion for receiving the substrate.

9. The substrate processing apparatus according to claim 1,
wherein the table body is made of quartz.

10. The substrate processing apparatus according to claim 9,
wherein the substrate mounting portion is made of aluminum nitride or silicon carbide.

11. The substrate processing apparatus according to claim 1,
wherein the turntable includes plural of the substrate mounting portions formed along a rotational direction of the turntable.

12. The substrate processing apparatus according to claim 1,
wherein the substrate mounting portion is positioned from the one surface to the opposite surface of the turntable.

13. The substrate processing apparatus according to claim 1, further comprising:
plural reaction gas supplying units respectively supplying reaction gasses onto the substrate mounted on the turntable;
separating areas provided between the reaction gas supplying units for separating the reaction gasses supplied from the plural reaction gas supplying units; and
an evacuation port for evacuating the process chamber.

14. The substrate processing apparatus according to claim 1,
wherein the substrate mounting portion includes a material, as a major constituent, having a coefficient of thermal conductivity higher than that of a material mainly composing the other portion of the turntable.

15. A film deposition apparatus for forming a film on a substrate, comprising:
a process chamber;
a turntable rotatably provided in the process chamber for mounting a substrate on one surface of the turntable and including a substrate mounting portion at which the substrate is to be mounted and a table body which is an other portion of the turntable, the substrate mounting portion being configured to have a heat capacity smaller than that of the table body; and
a heater that heats the substrate from an opposite surface side of the turntable.
